(19) United States
(12) Patent Application Publication
(10) Pub. No.: US 2024/0290581 A1
(43) Pub. Date: Aug. 29, 2024

(54) PLASMA PROCESSING APPARATUS

(71) Applicant: Hitachi High-Tech Corporation, Minato-ku, Tokyo (JP)

(72) Inventors: Shengnan Yu, Tokyo (JP); Takashi Uemura, Tokyo (JP); Kohei Sato, Tokyo (JP)

(21) Appl. No.: 18/025,766

(22) PCT Filed: Mar. 9, 2022
(86) PCT No.: PCT/JP2022/010245

§ 371 Date: Mar. 10, 2023

(51) Int. Cl. H01J 37/32

(52) U.S. Cl. CPC H01J 37/32724; H01J 37/32816; H01J 2237/24585; H01J 2237/334

(57) ABSTRACT

A plasma processing apparatus includes a sample table base that is placed on a periphery of a sample table, a pressure sensor that is connected to the sample table base through a connecting pipe and a buffer part, a heater that forms a temperature gradient in which temperatures of the connecting pipe and the buffer part rise toward the pressure sensor, and adjusts heating to bring the pressure sensor to a temperature similar to a plasma generation space above the sample table, and a rectangular base plate that is placed under the sample table base. The pressure sensor is stored in a place partitioned by a heat insulating plate at a corner of the base plate outside the sample table base on the rectangular base plate, and an inside and an outside of the corner part are communicated with each other through an opening.

### TECHNICAL FIELD

The present invention relates to a plasma processing apparatus that processes a substrate-like sample such as a semiconductor wafer supported on a sample table placed in a processing chamber inside a vacuum vessel using a plasma formed in the processing chamber, and particularly to a plasma apparatus that processes the sample while adjusting a pressure in the processing chamber using an output of a pressure gauge that detects the pressure inside the processing chamber.

### BACKGROUND ART

During processing of a semiconductor wafer (sample), a plasma processing apparatus is required to set a pressure inside the processing chamber to a desired value within a range suitable for laser processing over a long period of time and with high accuracy. Such a pressure inside the processing chamber is detected using a pressure gauge attached to the vacuum vessel in communication with the inside of the processing chamber, and a value of the pressure inside the processing chamber is adjusted using a value of the pressure detected from an output value of the pressure gauge.

On the other hand, it has been known that such pressure gauges have a so-called dependence on temperature (the output value of a pressure gauge is temperature-dependent), where the output value differs even at the same pressure value depending on the temperature to be detected. Also, it has been known that the output value of a pressure gauge has a time-varying property (a fluctuates over time (the output value of the pressure gauge has a time-varying property), such that the output value fluctuates from an initial state as an elapse of an operating time of the plasma processing apparatus or a cumulative number of scarce processing increases. Therefore, when the operating time of the plasma processing apparatus has reached a predetermined period or when the cumulative number of processing of semiconductor wafers (samples) has reached a predetermined processing amount, calibration work for correcting the output value of the pressure gauge and its accuracy is carried out after arrival.

On the other hand, in order to improve the accuracy of processing the wafer, the plasma processing apparatuses in recent years have been developed in which a sample table supporting a wafer is placed in the center of a processing chamber in the vertical direction of the processing chamber, and the processing chamber is configured by a discharge area which is a space above a top surface of the sample table where plasma is formed internally, an exhaust area which is a space below a bottom surface of the sample table and faces an exhaust port located directly below the bottom surface, and a space on an outer peripheral side of an outer wall of the sample stage that connects and communicates between those spaces. In such technology, a circumferential variation in the flow of gas and particles within the processing chamber from a space (discharge area) above the top surface of the sample table where the plasma is formed to the exhaust area is reduced, and processing accuracy is improved.

A known example of the above plasma processing apparatus has been disclosed in WO 2021/149212 (PLT 1). PLT 1 discloses a plasma processing apparatus in which a vacuum vessel surrounding a processing chamber includes an upper vessel, a lower vessel, a ring-shaped member sandwiched between the upper vessel and the lower vessel, and a discharge space forming a plasma above a top surface of the sample table, and a space facing an exhaust port below a bottom surface of the sample table are provided, and the sample table is supported between those spaces in a vertical direction. Furthermore, PLT 1 discloses a technology that eliminates a need for calibration work of a control pressure gauge, which is performed under an atmospheric pressure, by a calibration pressure gauge connected to a space connected to the processing chamber in addition to the control pressure gauge connected to a ring-shaped member held between the upper and lower vessels and communicating with an inside of the processing chamber.

### CITATION LIST

### Patent Literature

PTL: WO 2021/149212

### SUMMARY OF INVENTION

### Technical Problem

However, PTL 1 suffers from a problem because the following points have not been sufficiently considered.

In other words, in PTL 1, the pressure gauge is placed at a distance from the space above the top surface of the sample table where the plasma is formed. Therefore, when a plasma is formed, a place surrounding the space in question is heated, but when there is a large difference between a temperature of the place separated from the plasma where the pressure gauge is placed and a temperature of an area where the plasma is formed, a difference in temperature detected by the pressure gauge also increases due to the large difference, and the processing of a wafer, which is performed by adjusting the pressure in the processing chamber using an output of the pressure gauge, largely fluctuates or deviates from an intended processing.

Furthermore, in order to solve such problems, it is conceivable that a configuration for heating the pressure gauge and adjusting the temperature is applied. In this case, in a unit that detects a pressure which is configured by plural members, the pressure gauge is generally placed at an end of the plasma processing apparatus. At this time, if the surroundings of the pressure gauge do not sufficiently exhaust heat, a pressure sensor provided within the pressure gauge is heated excessively, and an accuracy of pressure detection is impaired. This point has not been taken into account, either.

Thus, in PTL 1, sufficient consideration has not been given to a reduction in an error in the temperature to be detected due to the distance between the place where a pressure is detected and a detection target. For this reason, no consideration has not been given to a fact that the reproducibility of processing a wafer or the accuracy of the shape after processing as a processing result has been impaired as a result of processing, and a processing yield has been impaired.

An object of the present invention is to provide a plasma processing apparatus with improved yield.

### Solution to Problem

A plasma processing apparatus includes a sample table base that is placed on a periphery of a sample table, a pressure sensor that is connected to the sample table base through a connecting pipe and a buffer part, a heater that forms a temperature gradient in which temperatures of the connecting pipe and the buffer part rise toward the pressure sensor, and adjusts heating to bring the pressure sensor to a temperature similar to a plasma generation space above the sample table, and a rectangular base plate that is placed under the sample table base. The pressure sensor is stored in a place partitioned by a heat insulating plate at a corner of the base plate outside the sample table base on the rectangular base plate, and an inside and an outside of the corner part are communicated with each other through an opening.

### Advantageous Effects of Invention

Structurally, the pressure sensor located at the end maintains a large temperature difference with a high-temperature buffer part to improve an exhaust heat, suppresses overheating, and reduces a detection error of the pressure sensor. As a result, variations in wafer processing conditions are reduced, and a processing yield is improved.

### BRIEF DESCRIPTION OF DRAWINGS

FIG. 1 is a perspective view showing an outline of a configuration of a plasma processing apparatus according to an example of the present invention.

FIG. 2 is a cross-sectional view showing an outline of a configuration of a plasma processing apparatus according to an example of the present invention.

FIG. 3 is a top view showing schematically an outline of a configuration around a sample table base of the plasma processing apparatus according to the example shown in FIG. 2.

FIG. 4 is a cross-sectional view showing schematically an outline of a configuration of a vacuum gauge unit of the plasma processing apparatus according to the example shown in FIG. 2.

FIG. 5 is a perspective view showing schematically the outline of the configuration of the vacuum gauge unit of the plasma processing apparatus according to the example shown in FIG. 2.

FIG. 6 is an enlarged perspective view showing a configuration of a cover according to the plasma processing apparatus according to the example shown in FIG. 1.

FIG. 7 is a diagram illustrating a heater of the vacuum gauge unit shown in FIG. 4.

### DESCRIPTION OF EMBODIMENTS

The embodiments of the present invention will be described below with reference to the drawings.

### Example

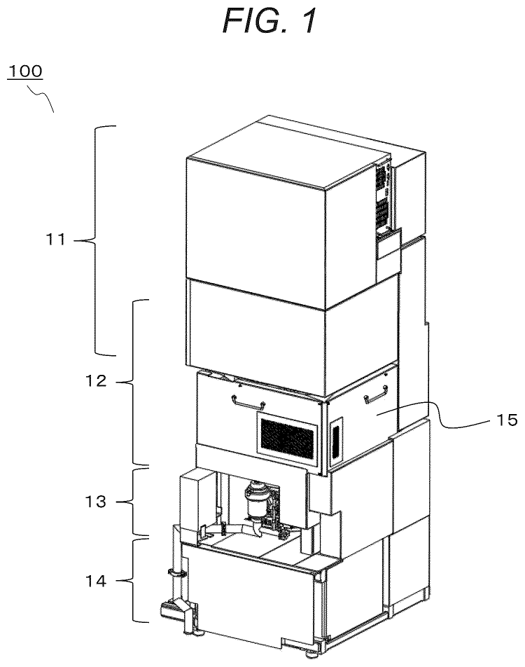

An example of the present invention will be described with reference to FIGS. 1 to 7.

FIG. 1 is a perspective view showing an outline of a configuration of a plasma processing apparatus according to an example of the present invention. A plasma processing apparatus 100 shown in FIG. 1 configures a part of a vacuum processing apparatus including at least one vacuum transport container not shown, and its side wall is a processing unit connected to one vacuum transport container in which substrate-like samples to be processed such as semiconductor wafers are transported internally. As will be described later, the plasma processing apparatus 100 is a processing unit with a vacuum vessel inside, in which an unprocessed wafer is loaded into a processing chamber inside a vacuum vessel while being placed on an arm tip of a transport robot disposed in the transport container inside the vacuum transport container, and the processed wafer is carried out from the processing chamber into the transport container.

The plasma processing apparatus 100 has an approximate rectangular shape when viewed from above, and a lowest part thereof is provided with a mounting part 14 having a rectangular shape, with a built-in interface for exchanging signals and gases among a power supply to perform operation to process a wafer inside the vacuum vessel, equipment for relaying a power, a vacuum processing apparatus body, and a building where the vacuum processing apparatus is installed. A vacuum pump such as a turbo molecular pump, and an exhaust part 13 including the vacuum pump, which are placed above a top surface of the mounting part 14, a vacuum vessel part 12 having the vacuum vessel that incorporates the processing chamber in which a processing gas is supplied inside and a wafer is processed, and a valve box that internally has a gate valve and a valve box having an interface function for coupling the vacuum vessel and the vacuum transport container, and a plasma forming part 11 including a power supply or a coil and a member for forming and supplying an electric field or a magnetic field for forming a plasma used for processing the wafer using the processing gas in the processing chamber inside the vacuum vessel are placed from bottom to top in a stated order.

In FIG. 1, a vertical area between the plasma forming part 11 and the vacuum vessel part 12 partially overlaps with each other because the plasma processing apparatus 100 in the present example forms a frame using an ECR (Electron Cyclotron Resonance) generated by an electric field and a magnetic field of p-wave, as described later, and a solenoid coil covers a partial outer periphery of an upper part of the vacuum vessel.

Furthermore, in the plasma processing apparatus 100 in the present example, the peripheries of the plasma forming part 11 and the vacuum vessel part 12 are covered by a cover (side wall cover) 15, each including a plate member with rectangular surfaces combined. The cover 15 is detachably attached to an unillustrated outer frame provided by each of the plasma forming part 11 and the vacuum vessel part 12, and four directions of the front, back, right, and left of those peripheries are covered with plate members. Thus, each outer wall surface of the plasma forming part 11 and the vacuum vessel part 12 covered with the cover 15 is shaped to a cuboid or a shape approximating the cuboid as a substantial cuboid.

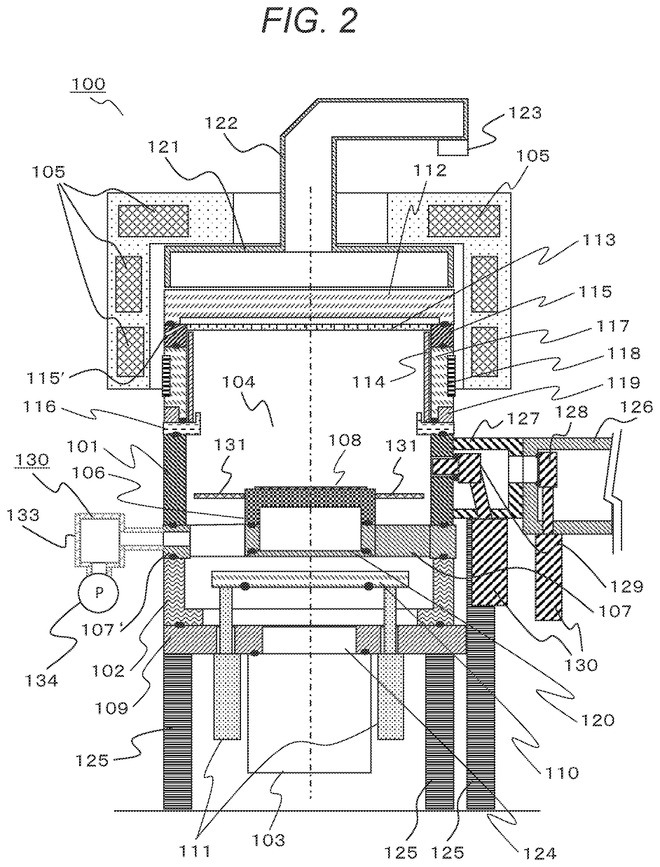

FIG. 2 is a cross-sectional view showing an outline of a configuration of a plasma processing apparatus according to an example of the present invention. A plasma processing apparatus 100 shown in FIG. 2 includes a vacuum vessel that is roughly divided into a vacuum vessel including a base plate 109 having a circular exhaust port 124 in the center, an upper vessel 101 placed above the base plate 109 and having a cylindrical inner side wall surface, a lower vessel 102 placed below the upper vessel 101, and a sample table base 107 sandwiched between those vessels. Furthermore, a bottom surface of the vacuum vessel is provided with an exhaust part including an exhaust pump 103 such as a turbo molecular pump placed in connection with the vacuum vessel. Furthermore, a plasma forming part having a waveguide 122 and a solenoid coil 105 in which an electric field of a predetermined frequency for forming a plasma in a space inside the vacuum vessel propagates inside is placed above the vacuum vessel.

Outer wall surfaces of the upper vessel 101, the lower vessel 102, and the sample table base 107 face the atmosphere around the plasma processing apparatus 100, and inner wall surfaces of those members surrounds a periphery of a processing chamber 104, which is a space in which a pressure is reduced by the exhaust pump 103 to form a plasma. The inner wall surfaces of these members have a cylindrical shape with a circular cross section in a horizontal direction, and the inner wall surfaces thereof are pressed vertically across a sealing member such as an O-ring so that steps at seams of the inner wall surfaces can be reduced as much as possible at a position where a center of a cylindrical shape of the processing chamber 104 surrounded by the respective members matches in the vertical direction or a position approximated to a degree regarded as matching, positioned, and connected mutually. When connected in this way, these members form a vacuum partition, and a space between the inside of the processing chamber 104 and the external atmosphere is airtight compartmentalized.

An upper space of the processing chamber 104 is a space where a plasma is formed as a discharge part, and a sample table 106 having a top surface on which a wafer 108 to be processed is placed is placed below the plasma formation space. The processing chamber 104 in the present example has a space defined by a bottom surface of the processing chamber 104, which is below a bottom surface of the sample table 106, and a circular opening of an exhaust port 124 through which particles such as dust and plasma in the processing chamber 104 are discharged is provided in a bottom surface of the processing chamber 104 below a bottom surface of the sample table 106.

Above the upper vessel 101, an earth ring 116 having a ring shape and made of a conductive member, a discharge block base 119 placed on a top surface of the earth ring 116 and having a ring shape, and a discharge part container 117 placed on the discharge block base 119 and surrounding an outer circumference of the discharge part and having a cylindrical shape are placed. A cylindrical inner side wall portion of the discharge part container 117 is disposed to cover a side wall on the inner periphery side of the discharge block base 119, and a quartz inner cylinder placed to cover the inner wall surface of the discharge part container 117 is placed between the cylindrical inner side wall portion of the discharge part container 117 and a discharge part which is a space inside the discharge part container 117 where a plasma is formed, thereby suppressing an interaction between the plasma and the inner wall of the discharge part container 117 to reduce damage and wear.

On an outer wall surface of the discharge part container 117, a heater 118 is wrapped around an outer periphery of the wall surface and placed in contact with the wall surface. The heater 118 is electrically connected to a DC power supply not shown, supplied with a current from the DC power supply to generate heat, and a temperature of the inner wall surface of the discharge part container 117 is adjusted to a value within a desired range.

An earth ring 116, which is a ring-shaped member made of a conductive material, is placed between lower end surfaces of the discharge part container 117 and the discharge block base 119 and an upper end surface of the upper vessel 101 placed underneath. A top surface of the earth ring 116 is connected to a bottom surface of a lower end of the cylindrical part of the discharge part container 117, and a lower surface of the earth ring 116 is further connected to a top surface of an upper end of the upper vessel 101 across an O-ring, and a force pressing those members in the vertical direction is supplied so that the inside and outside of the processing chamber 104 is airtightly sealed. The earth ring 116, although not shown, is electrically connected to a ground electrode, and when an end of the earth ring 116 on the inner circumferential side protrudes from a periphery to a center side of the discharge part inside the processing chamber 104 and comes into contact with a plasma, a potential of the plasma is adjusted to a value within an owner's desired range. Furthermore, above the top surface of the inner circumferential end of the earth ring 116, an inner cylinder 114 is placed with a gap from the inner wall surface of the discharge part container 117.

Furthermore, above an upper end of the discharge part container 117, a gas ring 115, which is a ring-shaped member with a passageway for processing gas supplied to form a plasm in the processing chamber 104, is placed across an O ring. Above a top surface of the gas ring 115, a window member 112 having a disc shape, which is a member made of a dielectric such as quartz, which forms a vacuum vessel and passes through an electric field supplied to the discharge part, is placed across an O-ring, and a bottom surface of an outer edge of window member 112 and a top surface of the gas ring 115 are connected with each other.

A shower plate 113, which is a disc-shaped member made of a dielectric such as quartz is placed below a bottom surface of the window member 112 across a gap, and covers an upper part of the discharge part of the processing chamber 104 to form its top surface. Multiple through holes are placed in a circular area in the center of the shower plate 113. The interior of the gas ring 115 is provided with a supply path for a processing gas, which is connected to a gas source configured by multiple tanks not shown across a flow controller (mass flow controller, MFC) through piping, and a gas flow path 115′ communicated to a gap between the window member 112 and the shower plate 113. A gas from various gas sources whose flow rate or speed has been adjusted by a flow controller is supplied along the piping and merges as one gas supply channel, then flows into the gap between window member 112 and the shower plate 113 through the gas flow path 115′ within the gas ring 115 and diffuses within the gap, and then is introduced from above into the processing chamber 104 through multiple through holes in the center of the shower plate 113.

The window member 112, the shower plate 113, the gas ring 115, the discharge part container 117, and the discharge block base 119 are connected to each other across an O-ring to form a vacuum vessel, and configures a discharge block in cooperation with the inner cylinder 114. The discharge block is configured to move in a vertical direction along a vertical axis of a lifter not shown as will be described later and to enable the vacuum vessel to be disassembled or assembled. The discharge block may be configured to include the earth ring 116, or may be configured to divide the vacuum vessel up and down between the upper vessel 101 and the earth ring 116 in a disassemble manner.

Above the window member 112, the waveguide 122 for propagating the electric field of micro waves supplied to form a plasma to the discharge part of the processing chamber 104 is placed. The waveguide 122 is provided with a cylindrical circular waveguide part that extends along a vertical axis and has a circular horizontal cross section perpendicular to the vertical axis, and a square waveguide part extending along a horizontal axis and having a rectangular or square vertical cross section perpendicular to the horizontal axis and whose one end is connected to an upper end of the circular waveguide part, and a magnetron 123 that oscillates to form an electric field is placed on the other end of the square waveguide part. The formed electric field of micro waves propagates horizontally through the square waveguide part, changes its direction at the upper end of the circular waveguide part, and propagates toward the processing chamber 104 below the lower window member 112.

The lower end of the circular waveguide part is connected to a center of a circular ceiling part of a cylindrical cavity part 121 having an inner diameter of the same size as that of the window member 112 or a size approximately equal to the window member 112, below the lower end of the circular waveguide part and above the window member 112. The inside of the circular waveguide part and the cavity inside the cavity part 121 are communicated with each other through a circular opening equal to the inner diameter of the circular waveguide in the center of the circular ceiling, and the cavity part 121 forms a part of the waveguide 122. The electric field of micro waves propagated within the circular waveguide is introduced into the cavity part 121, and then a desired electric field motor is formed inside the cavity part 121, penetrates through the window member 112 and the lower shower plate 113, and propagates into the processing chamber 104.

Furthermore, in the present example, multi-stage ring-shaped coils 105 are placed along with a yoke in the vertical direction, while surrounding the outer periphery side of the circular waveguide part of the waveguide 122 above the cavity part 121, the cavity part 121, and the outer periphery side of the cylindrical outer side wall of the discharge part container 117. Those solenoid coils 105 are electrically connected to a DC power supply not shown and supplied with a DC current to generate a magnetic field. The electric field of micro waves supplied from the waveguide 122 and the magnetic field generated and supplied from the solenoid coils 105 interact within the processing chamber 104 to generate electron cyclotron resonance (Electron Cyclotron resonance, ECR), excite the atoms or molecules of the processing gas supplied into the processing chamber 104, and ionize or dissociate the atoms and the molecules to form a plasma in the discharge part during processing of the wafer 108.

The sample table 106 is placed in the center of the inside of the ring-shaped sample table base 107, and is connected by the sample table base 107 by multiple support beams connecting between the sample table 106 and the sample table base 107. The support beams in the present example are placed radially on a so-called axisymmetrically for each angle identical in the circumferential direction when viewed from above or approximate to the extent regarded as identical with respect to the center axis of the cylindrical sample table 106 in the vertical direction, as shown by a dotted line in the figure. With such a configuration, particles such as a plasma formed in the discharge part inside the upper vessel 101, a gas supplied, and reaction products generated during the processing of the wafer 108 pass through spaces between the sample table 106 and the upper vessel 101 and between the sample table 106 and the sample table base 107, and between the support beams, passes through a space inside the lower vessel 102, and passes through the exhaust port 124 directly below the sample table 106, and are discharged due to the operation of the exhaust pump 103, and a flow of particles within the processing chamber 104 above the top surface of the wafer 108 is reduced in variation in the direction of circumferential direction of the wafer 108, and the uniformity of processing of the wafer 108 is improved.

The sample table 106 has a space inside, and the space is sealed by airtight sealing the inside and outside of the sample table bottom lid 120 on the bottom surface. Furthermore, a passage communicated with the atmospheric pressure atmosphere outside of the sample table base 107 is placed inside the multiple support beams, and the space inside the sample table 106 is communicated to the outer part. The space and the passage are areas for placing supply lines such as cables, piping, etc. that supply fluids such as electricity, refrigerant, gas, etc. to the sample table, which are placed on the outside of the sample table base 107. The passage and the space within the sample table 106 are at the same atmospheric pressure as the atmosphere or a pressure approximate to the atmospheric pressure.

Also, the upper vessel 101 and the lower vessel 102 have flange parts not shown on their respective outer walls. The flange parts of the lower vessel 102 and the upper vessel 101 above the lower vessel 102 are fastened and positioned with respect to the base plate 109 by screws and bolts. In other words, the lower vessel 102 is placed above the base plate 109, the sample table base 107 is placed above the lower vessel 102, and the upper vessel 101 is placed above the sample table base 107. Note that the outer periphery side walls of the upper vessel 101, the lower vessel 102, and sample table base 107 in the present example have a cylindrical shape, but those members may have other shapes even if the horizontal cross-sectional shape is rectangular rather than round.

The base plate 109 is connected to upper ends of multiple pillars 125 on a floor of a building such as a clean room where the plasma processing apparatus 100 is installed, and is supported by being placed on those pillars 125. In other words, a vacuum vessel containing the base plate 109 is positioned on the floor surface of a building through the multiple pillars 125.

Furthermore, an exhaust pumps 103 is placed in a space between the pillars 125 below the base plate 109 and are communicated to the processing chamber 104 through the exhaust port 124. A vertical axis passing through a center of a circular opening of the exhaust port 124 directly below the sample table 106 is placed in a position that matches or is approximate to the center axis described above, and an exhaust port lid 110 having a substantially disc shape that blocks or moves vertically with respect to the exhaust port 124 is placed inside the processing chamber 104 above the exhaust port 124. The exhaust port lid 110 moves up and down by the operation of an exhaust controller 111 placed below the base plate 109 and having a driving equipment such as an actuator, to thereby perform a function of a flow rate adjustment valve that increases and decreases a conductance of the exhaust of particles in the processing chamber 104 from the exhaust port 124 by increasing and decreasing an area of a flow path of the particles in the processing chamber 104 discharged from the exhaust port 124. The exhaust port lid 110 is driven based on a command signal from a control unit not shown to adjust the amount and speed of the internal particles exhausted by the exhaust pump 103.

The vacuum vessel of the plasma processing apparatus 100 is another vacuum vessel placed horizontally adjacent to the plasma processing apparatus 100, and is connected to a vacuum transport container 126 in which a transport robot is placed to hold the wafer 108 on a top surface of a tip of the arm and transport the wafer 108 to a transport chamber, which is a space in which a pressure is reduced. Between the plasma processing apparatus 100 and the vacuum transport container 126, the internal processing chamber 104 and a vacuum transport container are communicated with each other through a gate, which is a passage through which the wafer 108 passes inside. Furthermore, the vacuum transport container is equipped with a gate valve 128 that moves vertically and moves horizontally with respect to an inner wall surface of the vacuum transport container 126, opens the opening of a gate placed on the inner wall surface, and closes the opening airtight by abutting the inner wall surface across an O-ring.

Furthermore, in the present example, a valve box 127 with another gate valve 129 in an internal space is placed between the upper vessel 101 and the vacuum transport container 126. The valve box 127 internally has a space airtightly compartmented from an external atmospheric pressure atmosphere by connecting each of two ends of the valve box 127 to each of the outer side wall surface of the upper vessel 101 and the side wall surface of the vacuum transport container 126 across a seal member such as an O ring. The side wall surface of one end of the valve box 127 is connected to the periphery of the opening of the gate on the side wall of the vacuum transport container 126, and the side wall surface of the other end is connected to the periphery of the gate opening placed on the side wall of the upper vessel 101 so that a space within the valve box 127 configures a passage where the wafer 108 is placed on the arm of the transport robot and transported.

Note, a gate valve 129 placed inside the valve box 127 moves vertically and moves horizontally with respect to the outer wall of the upper vessel 101, and is sealed airtight by opening the opening of the gate of the upper vessel 101 or abutting the opening across an O-ring. A drive 130 such as an actuator is placed below each of the vacuum transport container 126 and the valve box 127 by connecting to the gate valves 128 and 129 placed inside of those members for moving those members.

Also, the valve box 127 in the present example is connected to an upper end of another pillar 125 whose lower end is connected and positioned to a floor surface of a building by screws, bolts, or the like and supported by the pillar 125, and positioned and placed so that a side wall surface of one end of the valve box 127 is connected to an outer wall surface of the upper vessel 101 on the gate outer circumference side across an O-ring to realize airtight sealing. In addition to being supported by the pillar 125 on the floor surface of a building, the valve box 127 in the example in FIG. 1 may also be supported by another pillar 125 connected to the pillar 125 below the base plate 109, or secured with screws, bolts, or the like on the upper side of the end of the base plate 109 on the vacuum transport container 126 side.

Prior to processing of the wafer 108, the wafer 108 before processing is placed on the top surface of the tip of the arm of the transport robot and held inside the processing chamber 104 that has been depressurized in advance, and carried in from the vacuum transport container through a space inside the valve box 127. When the wafer 108 is transferred from a state held on the arm above the top surface of the sample table 106 inside the processing chamber 104 to multiple pins protruding from the top surface of the sample table 106, the arm of the transport robot leaves the processing chamber 104 into the vacuum transport container. The wafer 108 is placed on the top surface of the sample table 106, and the gate valve 129 is driven so that the gate of the upper vessel 101 is airtight closed.

In this state, a processing gas containing multiple gases whose flow rate or speed has been adjusted by the flow controller is introduced into the processing chamber 104 through the gap between the window member 112 and the shower plate 113 and the through holes of the shower plate 113 from the gas supply line and gas flow path 115′, and the gas particles in the processing chamber 104 are exhausted due to the operation of the exhaust pump 103 connected to the exhaust port 124, and the pressure in the processing chamber 104 is adjusted to a value within a range suitable to processing by balancing of introduction and exhaust. Furthermore, a macro-wave electric field formed using the magnetron 123 propagates through the waveguide 122 and the cavity part 121, passes through the window member 112, the shower plate 113, and is supplied to the processing chamber 104, and a magnetic field formed by the solenoid coil 105 is supplied to the processing chamber 104, and a plasma is formed in the discharge part using gas for processing.

While the wafer 108 is placed and held on the top surface, a high-frequency power of a predetermined frequency is supplied to an unillustrated electrode placed inside the sample table 106, and a bias potential having a difference from the plasma is formed above the top surface of the wafer 108, and charged particles such as ions in the plasma are attracted to the top surface of the wafer 108, and collide with a film layer to be processed in a film structure having the film layer to be processed pre-placed on the top surface of the wafer 108 and a mask layer made of a material such as resist stacked above the film layer to progress etching processing.

When the etching processing of the film layer to be processed reaches a predetermined remaining film thickness or depth and is detected by a detector not shown, the supply of a high-frequency power to electrodes inside the sample table 106 and the formation of the plasma are stopped, and the etching processing is completed. Next, after sufficiently exhausting the particles inside the processing chamber 104, the gate valve 129 is driven, the gate of the upper vessel 101 is opened, and the arm of the transport robot enters the processing chamber 104 through the gate, the wafer 108 is transferred from the sample table 106 onto the arm, the arm exits the processing chamber 104, and the processed wafer 108 is carried out to the vacuum transport container.

The control unit determines whether there is an unprocessed wafer 108 to be processed next, and when the next wafer 108 is present, the wafer 108 is carried into the processing chamber 104 through the gate again and transferred to the sample table 106, and then etching processing of the wafer 108 is performed in the same way as above. When it is determined that there is no wafer 108 to be processed next, the operation of the plasma processing apparatus 100 for processing the wafer 108 to manufacture a semiconductor device is stopped or suspended.

A vacuum gauge unit 130 with a pressure sensor 134 that is connected to the inside of the processing chamber 104 and detects a pressure inside the processing chamber 104 is connected to a cylindrical or ring-shaped sample table ring base 107′ located on the outer periphery side of the sample table 106 of the sample table base 107 in the plasma processing apparatus 100 according to the present example. The vacuum gauge unit 130 is provided with a pressure sensor 134, a buffer chamber (buffer part) 133 connected to the pressure sensor 134, and a pipeline connecting the buffer chamber 133 to the sample table ring base 107′. Furthermore, an end of the pipeline of the vacuum gauge unit 130 is connected to the sample table ring base 107′, the sample table ring 107′ is connected to a through hole that passes in the left and right directions on the drawing, and the pressure sensor 134 is connected to the inside of the processing chamber 104, so that the pressure sensor 134 can detect the pressure inside the processing chamber 104.

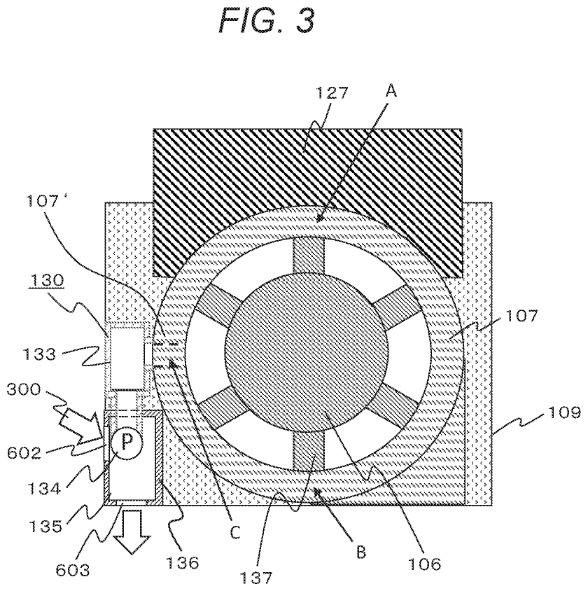

FIG. 3 is a top view showing schematically an outline of the configuration around the sample table base of a plasma processing apparatus according to an example shown in FIG. 2. FIG. 3 shows a diagram where a part of the sample table base 107 of the plasma processing apparatus 100 shown in FIG. 2 and below the sample table base 107 is viewed from above. Also, in FIG. 3, a valve box 127 connected to a top surface of the end of the base plate 109 on the vacuum transport container 126 side (upper side of the drawing) to which the plasma processing apparatus 100 is connected is viewed from the top.

Furthermore, FIG. 3 shows a horizontal cross-sectional view of a part of the vacuum gauge unit 130 connected to the sample table ring base 107′ taken on a horizontal surface at a height at which the vacuum gauge unit 130 is placed. As shown in FIG. 3, in the vacuum gauge unit 130, the pressure sensor 134 placed at one end of the vacuum gauge unit 130 is connected to the sample table ring base 107′ by means of a buffer chamber 133 connected to the pressure sensor 134 and a pipeline, and a path for a flow of gas and particles inside the processing chamber 104 through communication between the pressure sensor 134 and the inside of the processing chamber 104 is configured between the pressure sensor 134 and the processing chamber 104.

In other words, an end of the pipeline connected between the buffer chamber 133 and the sample table ring base 107′ and corresponding to the other end of the vacuum gauge unit 130 is connected to the side wall surrounding the through hole extending in the left and right directions in the drawing, which is an outer periphery side wall of the sample table ring base 107′, so that the inside and outside of the side wall are hermetically sealed. The through hole is placed so as to communicate between the part of the outer periphery side wall surface and the inside at an intermediate position (C) between an end (first end) A of the sample table ring base 107′ on a side (upper side in FIG. 3) connected to the vacuum transport container 126 in which the valve box 127 is placed and an end (second end) B of the table ring base 107′ on an opposite side (lower side in FIG. 3) across the center of the sample table 106. The place where the through hole is installed is located between multiple support beams 137 supporting the sample table 106 in the center of the sample table ring base 107′. The support beams 137 radially extend at an equal angle around the axis of the center of the sample table 106 between the outer periphery side wall of the cylindrical sample table 106 and the cylindrical inner circumferential side wall of the sample table ring base 107′, and connect those members. With this configuration, the pressure sensor 134 is communicated with the inside of the processing chamber 104 through the buffer chamber 133, pipelines, and the through holes. As a result, the pressure sensor 134 can detect a pressure in the processing chamber 104, particularly, a pressure in an area of the processing chamber 104 in which a plasma is formed, a so-called discharge area, above a mounting surface of the sample table 106 on which the wafer 108 is mounted.

Meanwhile, as shown in FIG. 2, the sample table ring 107′ is sandwiched between the upper vessel 101 and the lower vessel 102 at a height sandwiched between those vessels. Therefore, the pressure sensor 134 is placed at a distance from the discharge area, which is a detection target, by at least as much as the height of the sample table 106, and the length of the pipeline and the buffer chamber 133. Furthermore, a plasma confinement ring 131 is placed on the outer periphery side of the sample table 106, and a place facing the discharge area of the plasma confinement ring 131 and the wafer 108 is heated from the plasma due to the plasma formed in the discharge area during processing, and is brought to a relatively high temperature. On the other hand, the pressure sensor 134 is installed away from the detection target (discharge area), and in a place where the temperature is different from the detection target (discharge area), the pressure sensor 134 is required to detect the pressure temperature of the detection target.

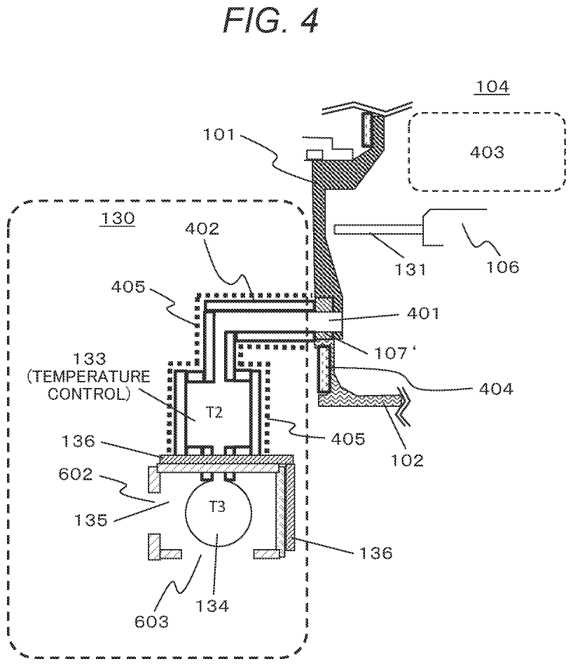

Therefore, as will be described later in FIG. 4, the vacuum gauge unit 130 in the present example has a configuration in which a heater 405 is placed around a part including the buffer chamber 133 and the pipeline between the pressure sensor 134 and the sample table ring base 107′, and those members are heated. With the heater 405, at least a part of the buffer chamber 133 and the pipeline is set to a temperature of the member facing the plasma while a plasma is formed in the discharge area. As a result, a gap between the pressure detected by the pressure sensor 134 and the pressure within the discharge are can be reduced. Thus, the accuracy of the pressure detected by the pressure sensor 134 can be improved. In particular, in this example, heating by an output from the heater 405 is adjusted so that the temperatures of various members such as pipeline configuring a path between the end of the vacuum gauge unit 130 connected to the sample table ring base 107′ and the pressure sensor 134, and the buffer chamber 133 increases towards the pressure sensor 134. In other words, the heater 405 forms a temperature gradient like “the temperature of the pressure sensor 134≥the temperature of the buffer chamber 133,” and the sensor part of the pressure sensor 134 is configured so that the sensor part of the pressure sensor 134 can adjust the temperature to an atmosphere approximate to a plasma generation space (discharge area).

Furthermore, as shown in FIG. 3, in this example, the pressure sensor 134 is provided with a buffer chamber 133 and the like between the pressure sensor 134 and the sample table ring base 107′ configuring the vacuum vessel, is separated from the vacuum vessel, and is placed above the vicinity of the corner (corner) of the lower left end of the base plate 109 in the drawing, with a gap open from the top surface of the base plate 109. Furthermore, the pressure sensor 134 is provided with a heat insulating plate 136 between the sample table ring base 107′ configuring the vacuum vessel and the lower vessel 102, and is placed in a cooling chamber 135 compartmented from the vacuum vessel and the vacuum chamber 133.

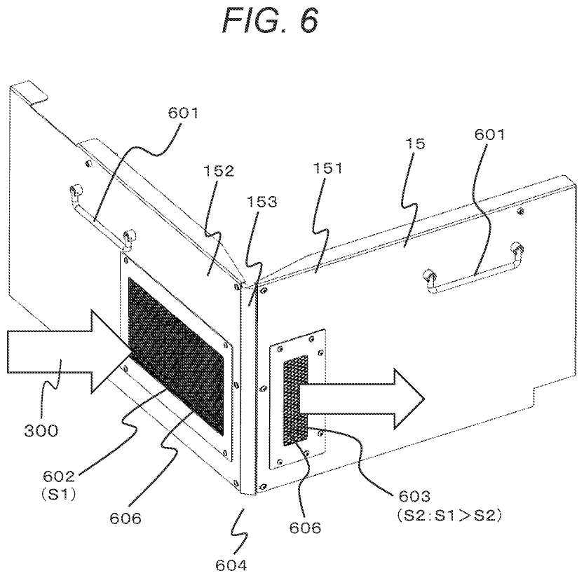

The cooling chamber 135 is communicated with the space surrounding the plasma processing apparatus 100 by openings 602 and 603 placed at at least two locations. A gas (atmosphere) 300 as an atmosphere outside of the plasma processing apparatus 100 flowing into the cooling chamber 135 from an opening (first opening) 602 in one place exchanges heat with the internal pressure sensor 134 or the members on the inner wall surface of the cooling chamber 135, and flows out of an opening (second opening) 603 at another place into a space outside the plasma processing apparatus 100. As a result, an increase in temperature on the outer wall surface of the pressure sensor 134 is suppressed. Also, when viewed from the top, the temperature of the pressure sensor 134 located at the end (corner) of the plasma processing apparatus 100 becomes excessively high, and damage to the accuracy of pressure detection is suppressed. The openings 602 and 603 will be described in more detail with reference to FIG. 6.

FIG. 4 is a cross-sectional view showing schematically an outline of the configuration of the vacuum gauge unit of the plasma processing apparatus according to the example shown in FIG. 2. FIG. 4 shows schematically the configuration of the vacuum vessel and the internal processing chamber 104 of this example, and the vacuum gauge unit 130 between the sample table ring base 107′ configuring the vacuum vessel and the pressure sensor 134 in the cooling chamber 135.

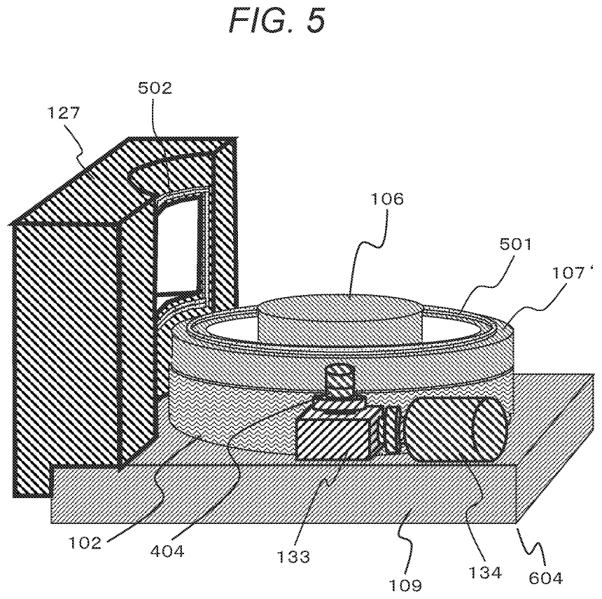

Furthermore, FIG. 5 is a perspective view showing schematically an outline of the configuration of the vacuum gauge unit in a plasma processing apparatus according to the example shown in FIG. 2. In FIG. 5, like FIG. 3, the placement of the sample table ring base 107′ below the upper vessel 101, the lower vessel 102, the base plate 109, the valve box 127, and the vacuum gauge unit 130 are schematically shown.

As described above, the pressure sensor 134 and the sample table ring base 107′ are connected by the vacuum chamber 133 and a connecting pipe (coupling pipe) 402 connecting the buffer chamber and the sample table ring base 107′. Furthermore, the end of the connecting pipe 402 is connected to the part surrounding the opening 401 of the through hole in the outer periphery side wall of the sample table ring base 107′. In the place where the connecting pipe 402 is connected to the outer peripheral side wall of the sample table ring base 107′, its axial direction extends in a horizontal direction perpendicular to the outer periphery side wall (left and right in FIG. 3) toward the buffer chamber 133, and further, the axial direction bends and extends downward at a place from the buffer chamber 133.

In this example, the connecting pipe 402 is bent multiple times at places until it is connected to the buffer chamber 133, and its axial direction is bent at 90 degrees or an angle approximate to 90 degrees. As a result, the buffer chamber 133 and the pressure sensor 134 connected to the buffer chamber 133 are located at places separated horizontally (downward in FIG. 3) toward an opposite side across the center of the sample table 106 (of the processing chamber 104) with respect to an end of the base plate 109 on a side where the valve box 127 is placed (a side of the plasma processing apparatus 100 connected to the vacuum transport container). As a result, the pressure sensor 134 is located in the corner on the opposite side across the center of the sample table 106 (of the processing chamber 104) of the base plate 109 having a rectangular flat shape. In such a place, a relatively large distance can be taken from the lower vessel 102 and the sample table ring base 107′, and the gas 300 as an external atmosphere can be effectively passed through at a place relatively close to the outside of the plasma processing apparatus 100.

In this state, the pressure sensor 134 is placed above the base plate 109, at a height facing the outer peripheral side wall of the lower vessel 102, with a gap from the side wall. As shown in FIG. 4 (omitted in FIG. 5), the heat insulating plate 136 is placed between the pressure sensor 134 and the cooling chamber 135 in which the pressure sensor 134 is housed inside, the vacuum chamber 133, the lower vessel 102, and the outer periphery side wall surface of the sample table ring base 107′. The cooling chamber 135 is compartmented from the lower vessel 102 and other spaces on the periphery of the sample table ring base 107′. In particular, the outer periphery side wall surface of the lower vessel 102 in this example is provided with a peripheral heater 404 to heat the lower vessel 102 and prevent particles inside the processing chamber 104 from adhering to and being deposited on the inner wall surface. As shown in FIG. 4 (omitted in FIG. 5), the outer wall surrounding the vacuum chamber 133 and the outer wall surrounding the connecting pipe 402 are heated by the heater 405 indicated by a thick dotted line. The heat insulating plate 136 reduces an influence of the outer wall of the pressure sensor 134 due to the heat of the peripheral heater 404 and the lower vessel 102 or the sample table ring base 107′ heated by the heater 404, and furthermore, the buffer chamber 133 and connecting pipe 402 heated by the heater 405. For that reason, the heat insulating plate 136 is formed of a member made of a material with high heat shielding performance. In other words, the pressure sensor 134 is stored in a place compartmented by the heat insulating plate at the corner of the base plate 109 on the outside of the sample table base 107 (sample table ring base 107′) above the rectangular base plate 109. Reference numeral 403 is a schematically shown plasma or an area (discharge area) where a plasma occurs.

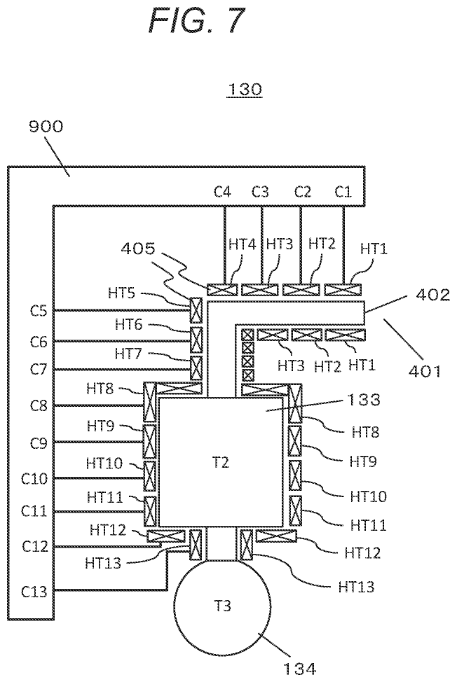

FIG. 7 is a diagram showing the beater of the vacuum gauge unit shown in FIG. 4. As shown in FIG. 7, the heater 405 provided on the vacuum gauge unit 130 includes multiple heater parts HT1 to HT13. The heater parts HT1 to HT13 are attached so as to heat the periphery of each member of the pipeline 402 and the buffer chamber 133 configuring a path between the opening 401 and the pressure sensor 134. Then, the heater parts HT1 to HT13 are connected to control lines C to C13, respectively, and the control lines C1 to C13 is connected to a heater control unit 900. Each of the heater parts HT1 to HT13 is individually configured so that its temperature can be adjusted and controlled by a voltage value or a current value of the control lines C1 to C13. The heater control unit 900 can adjust and control the heating temperature of the control heater parts HT1 to HT13 by controlling an output of the voltage value or current value of the control lines C1 to C13. In this example, the heater control unit 900 controls the output of the voltage values or current values of the control lines C1 to C13 so that the temperature of each member in the pipeline 402 and the buffer chamber 133 configuring the path between the opening 401 of the through-hole of the outer periphery side wall of the sample table ring base 107′ of the vacuum gauge unit 130 and the pressure sensor 134 rises toward the pressure sensor 134, and adjusts the heating of the heater parts HT1 to HT13. As the other configurations in FIG. 9 are identical with those in FIG. 4, a description thereof will be omitted.

As shown in FIG. 4, the cooling chamber 135, which is a space having a rectangular body or a shape approximate to the rectangular body has openings 602 and 603 at each location corresponding to two adjacent surfaces of the rectangular body. The cooling chamber 135 is communicated with a space outside of the plasma processing apparatus 100 through those openings 602 and 603. An increase in temperature on the outer wall of the pressure sensor 134 and the cooling chamber 135 is suppressed by the atmosphere (atmosphere) of the external space flowing into the cooling chamber 135 from one opening 602 of those openings 602 and 603. As a result, the pressure detection unit inside the pressure sensor 134 is communicated with the inside of the processing chamber 104 through the buffer chamber 133 heated to a temperature approximate to the temperature of the member facing the discharge face, and the pressure in the discharge area can be detected with high accuracy.

Note, in FIG. 5, the O-ring 501 is placed on the upper end of the sample table ring base 107′, deforms in contact with the lower end of the upper vessel 101 mounted on the sample table ring base 107′, and hermetically seals the inside and outside of the processing chamber 104. Similarly, the O-ring 502 is partially curved into a cylindrical shape of the valve box 127 and deformed by coming into contact with the cylindrical outer side wall of the upper vessel 101 placed on the sample table ring base 107′, and hermetically seals the inside and outside of the valve box 127 and the processing chamber 104.

FIG. 6 is a perspective view showing an enlarged view of the cover configuration of the plasma processing apparatus according to the example shown in FIG. 1. In particular, FIG. 6 shows the cover (side wall cover) 15 of the vacuum vessel part 12. The cover 15 is provided with two openings 602 and 603 at places that cover parts corresponding to two adjacent surfaces of the cooling chamber 135 having a rectangular body or a shape approximate to the rectangular body.

The cover 15 is detachably attached to the outer periphery of the vacuum vessel part 12 above the base plate 109, and in particular, in this example, the lower end of the cover 15 is connected to the base plate 109 and attached. In order to increase the safety of transportation or installation work, a handle 601 is placed at each of the two locations on the outer wall surface of the cover 15, which can be attached detachably.

The cover 15 in this example has a configuration in which two plate members 151 and 152 covering surfaces corresponding to each adjacent side of the rectangular shape of the seat plate 109 are connected in the outer periphery of the vacuum vessel on the rectangular base plate 109. Where the two plate members 151 and 152 face each other at a short distance, or an adjacent location 153 corresponds to the rectangular corner 604 of the base plate 109 (see FIG. 5), and the cooling chamber 135 of the vacuum gauge unit 130 is placed on the corner 604. Thus, the openings 602 and 603 are placed at the above adjacent locations on the two plate members 151, 152, respectively.

The external and internal cooling chambers 135 of the cover 15 are communicated with each other through each opening 602 and 603. In other words, each of the openings 602 and 603 is placed on the two plate members 151 and 152 of the cover 15 covering the two adjacent side surfaces of the cooling chamber 135, which has a rectangular shape placed above the corner of the base plate 109. The openings 602 and 603 in this example has a configuration in which a plate-like member 606 having a mesh or a porous shape is placed inside a through hole that passes through the plate members 151 and 152 in a rectangular shape.

Also, an opening area S1 of the opening 602 of the plate member 152 placed along a direction in which the axis of the connecting pipe 402 extends is set to be larger than an opening area S2 of the other opening 603 with respect to the pressure sensor 134 attached to an end of the connecting pipe 402 whose axis extends toward an opposite side to the valve box 127 across the sample table 106 or the buffer chamber 133 (S1>S2). The opening 602 is placed in a position facing the space between another adjacent plasma processing apparatus or atmospheric transport container while the plasma processing apparatus 100 is attached to the vacuum transport container to configure a vacuum processing apparatus. On the other hand, the opening 603 is placed in a position facing a space from adjacent another vacuum processing apparatus where a user of the apparatus can move. The atmosphere surrounding the plasma processing apparatus 100, which flows in from the space from another adjacent plasma processing apparatus or atmospheric transport container, exchanges heat with the outer wall of the pressure sensor 134 inside the cooling chamber 135, and flows out of the opening 603 to the outside of the plasma processing apparatus 100.

### Industrial Applicability

The present invention is applicable to a plasma processing apparatus that processes substrate-like samples such as semiconductor wafers using a plasma formed in a processing chamber.

### REFERENCE SIGNS LIST

100: plasma processing apparatus
101: upper vessel
102: lower vessel
103: vacuum pump (exhaust pump)
104: processing chamber
105: solenoid coil
106: sample table
107: sample table base
108: wafer
109: base plate
110: exhaust lid
111: exhaust air conditioner
112: window member
113: shower plate
114: inner cylinder
115: gas ring
115′: gas flow path
116: earth ring
117: discharge vessel
118: heater
119: discharge block base
120: sample table bottom lid
121: cavity part
122: waveguide
123: magnetron
124: exhaust port
125: pillar
126: vacuum transport container
127: valve box
128, 129: gate valve
130: vacuum gauge unit
133: buffer chamber
134: pressure sensor
135: cooling chamber
136: heat insulating version
405: heater
602, 603: opening
604: corner
C1 to C13: control line
HT1 to HT13: heater part
900: heater control unit

1. A plasma processing apparatus, comprising:
a sample table base that is placed on a periphery of a sample table;
a pressure sensor that is connected to the sample table base through a connecting pipe and a buffer part;
a heater that forms a temperature gradient in which temperatures of the connecting pipe and the buffer part rise toward the pressure sensor, and adjusts heating to bring the pressure sensor to a temperature similar to a plasma generation space above the sample table; and
a rectangular base plate that is placed under the sample table base,
wherein the pressure sensor is stored in a place partitioned by a heat insulating plate at a corner of the base plate outside the sample table base on the rectangular base plate, and
an inside and an outside of the corner part are communicated with each other through an opening.

2. The plasma processing apparatus according to claim 1,
wherein the sample table base is ring-shaped and has a through hole having an opening to which the connecting pipe is connected,
the connecting pipe and the buffer part are connected between the opening and the pressure sensor, and
the place where the pressure sensor is stored is outside of the ring-shaped sample table base on the rectangular base plate.

3. The plasma processing apparatus according to claim 1,
wherein the opening, which communicates through the inside and outside of the place, includes a first opening and a second opening provided on each of two side wall covers that are adjacent to each other through the corner of the base plate, and
an atmosphere outside the plasma processing apparatus flows from one side of the first opening and the second opening to the other of the first opening and the second opening.

4. The plasma processing apparatus according to claim 3,
wherein the outside atmosphere is made to flow from the first opening to the second opening, and
an opening area of the first opening is larger than that of the second opening.

5. The plasma processing apparatus according to claim 1, further comprising:
a plasma forming part that generates a plasma in the plasma generation space; and
a vacuum vessel part including the sample table,
wherein the vacuum vessel part includes an upper vessel, a lower vessel placed below the upper vessel, and the sample table bed sandwiched between the upper vessel and the lower vessel.

6. The plasma processing apparatus according to claim 2,
wherein the through hole is placed in an intermediate position between a first end of the sample table base on a side connected to the vacuum transport container and a second end of the sample table base on an opposite side through a center of the sample table.

7. The plasma processing apparatus according to claim 6,
wherein the connecting pipe is bent a plurality of times at places until it is connected to the buffer part, at 90 degrees or an angle approximating 90 degrees as substantial 90 degrees in an axial direction,
the buffer part and the pressure sensor are located at a place horizontally separated toward an opposite side across a center of the sample table with respect to an end of the side of the base plate, which is connected to the vacuum transport container, and
the pressure sensor is located in the corner on the opposite side of the base plate having a rectangular flat shape across the center of the sample table.
